(19) United States
(12) Patent Application Publication
(10) Pub. No.: US 2011/0084308 A1
(43) Pub. Date: Apr. 14, 2011

(54) SEMICONDUCTOR ARRANGEMENT AND A METHOD FOR MANUFACTURING THE SAME

(76) Inventors: Ter-Hoe Loh, Singapore (SG); Hoai-Son Nguyen, Singapore (SG)

(21) Appl. No.: 12/672,363

(22) PCT Filed: Aug. 8, 2007
(86) PCT No.: PCT/SG07/00244

§ 371 Date: Dec. 9, 2010

(51) Int. Cl. H01L 29/165; H01L 21/20

(52) U.S. Cl. 257/190; 438/479; 257/E29.085; 257/E21.09

(57) ABSTRACT

A method for manufacturing a semiconductor arrangement is disclosed. The method comprises forming at least one trench in a dielectric layer, thereby exposing a portion of a semiconductor substrate, forming a silicon-germanium buffer layer at least on the bottom of the at least one trench, forming a germanium seed layer on the silicon-germanium buffer layer and forming a germanium layer on the germanium seed layer. A semiconductor arrangement is also disclosed. The semiconductor arrangement comprises a semiconductor substrate, a dielectric layer disposed above the semiconductor substrate, at least one trench in the dielectric layer exposing a portion of the semiconductor substrate, a silicon-germanium buffer layer disposed above at least the bottom of the at least one trench, a germanium seed layer disposed above the silicon-germanium buffer layer and a germanium layer disposed above the germanium seed layer.

### FIELD OF THE INVENTION

Embodiments of the invention relate to field of semiconductor arrangements. By way of example, embodiments of the invention relate to an epitaxial structure of low temperature silicon germanium (SiGe) with Ge-seed layer prior to selective epitaxial growth (SEG) of Ge and a method for manufacturing the same.

### BACKGROUND OF THE INVENTION

Silicon (Si)-based complementary metal-oxide-semiconductor (CMOS) electronics device processing at front-end often involves thermal cycles with processing temperature greater than 900° C. On the contrary, for germanium-silicon (Ge/Si)-based electronics and optoelectronics devices, the presence of Ge demands relatively lower temperature processes for example less than about 700° C. This incompatibility in thermal budget imposes a key challenge in monolithic integration of Si-based CMOS electronics with Ge/Si-based devices.

Several attempts have been made to address this problem so as to enable monolithic integration of Si-based CMOS electronics with Ge/Si-based devices. One approach involves ultra-high vacuum chemical vapor deposition (UHVCVD) growth of Ge over Si via a compositionally graded SiGe buffer. Publication “Toward device-quality GaAs growth by molecular beam epitaxy on offcut Ge/Si₁₋ₓGeₓ/Si substrates”, R. M. Sieg et al, Journal of Vacuum Science & Technology B: Microelectronics and Nanometer Structures, May 1998, Volume 16, Issue 3, pp. 1471-1474 discloses that the epitaxial growth of Gallium Arsenide (GaAs) on Si substrates through the use of a Ge/graded Si₁₋ₓGeₓ/Si buffer layer would allow monolithic integration of GaAs-based opto-electronics with Si microelectronics.

Another approach involves utilizing a two-stage Ge growth on Si, which consists of deposition of Ge seed layer at a low temperature of about 350° C. to 450° C., followed by the deposition of Ge epitaxy at a higher temperature of about 500° C. to 850° C. Publication “High performance germanium-on-silicon detectors for optical communications”, Silvia Famà et al, Applied Physics Letters, July 2002, Volume 81, Issue 4, pp. 586-588 discloses that in order to minimize the dislocations associated with large lattice mismatch, a thin relaxed low-temperature Ge buffer was deposited on Si at 350° C. with 10 sccm of GeH₄. The buffer layer was meant to promote the insertion of dislocations as a mechanism for strain relaxation rather than island growth. Then the reactor temperature was increased to a higher temperature of 600° C. and about 4 μm of Ge were deposited on Si.

A similar approach is disclosed in publication “High-quality Ge epilayers on Si with low threading-dislocation densities”, Hsin-Chiao Luan et al., Applied Physics Letters, Volume 75, Issue 19, pp. 2909-2911. The publication discloses that high-quality Ge epilayers on Si with low threading-dislocation densities were achieved by a two-step UHVCVD process followed by cyclic thermal annealing. Heteroepitaxy of Ge on Si was initiated at 350° C. with a flow of 10 sccm of GeH₄. After 30 nm of Ge was deposited on Si, the furnace temperature was raised to 600° C. and 1 μm of Ge was deposited on Si. Then the wafers were cyclic annealed between a high annealing temperature and a low annealing temperature.

Recently a method of using ultra-thin low temperature Si₁₋ₓGeₓ buffer in the order of several nanometers, prior to growth of low-temperature Ge seed layer, followed by high temperature Ge epitaxy is described in publication “Growth of high quality Ge epitaxial layer on Si (100) substrate using ultra thin Si_{0.5}Ge_{0.5} buffer”, Junko Nakatsuru, Materials Research Society, Fall, EE 7.24, 2005. The publication discloses Si substrates were cleaned by dilute hydrofluoric acid (DHF) solution and annealed at 750° C. in vacuum before epitaxial growth. 2-20 nm Si₁₋ₓGeₓ buffer layers were grown at 450-520° C. A two-step growth process was then employed to grow Ge epitaxial layer on the buffer layer. First, a Ge seed layer of about 30 nm was grown at 350° C. to 400° C. and then a thicker Ge layer of about 1 μm was grown at 550° C. to 600° C. The resulting structure was treated with in-situ at about 800° C. annealing for about 15 minutes after growth of the thick Ge epitaxial layer.

Further using the method as disclosed in publication “Growth of high quality Ge epitaxial layer on Si (100) substrate using ultra thin Si_{0.5}Ge_{0.5} buffer” but without the cyclic annealing, another publication “Ultrathin low temperature SiGe buffer for the growth of high quality Ge epilayers on Si (100) by ultrahigh vacuum chemical vapor deposition” Ter-Hoe Loh et al., Applied Physics Letters, Volume 90, 092108 (2007) discloses that etch-pit-density (EPD) of 6×10⁶ cm⁻² in as-grown blanket Ge on Si can be achieved. Attaining EPD of Ge epitaxy in the order of 10⁶ cm⁻² while eliminating annealing results in lower thermal budget processing and reduces rampant dopant diffusion in the Si and Ge intermixing with Si. The suppression of Ge and Si intermixing is critical to maintain the band-gap characteristics which determines the photodiode response spectrum.

However, none of the prior art discloses a method to selectively grow high quality strained or strain-relaxed Ge epitaxy on patterned Si substrate. One application is the realization of optoelectronics integrated circuit (OEIC) using CMOS processing with Ge/Si as the photo-detector. Selective epitaxial growth (SEG) of Ge over designated areas of Si-based OEIC chip for the formation of Ge/Si photo-detector can be performed after the completion of front-end CMOS processing. This not only facilitates process integration but also eliminates the need to perform Ge etching for mesa formation, and also provide an added benefit of better crystal quality of Ge in comparison to blanket Ge epitaxy over a full wafer. This is due to the suppression of area-dependent interface defects nucleation sources such as dislocation interactions, particles and threading dislocations (TD) and the presence of mesa side wall acting as sinks for TD which can propagate more easily out to the edge of the SEG epitaxy.

### SUMMARY OF THE INVENTION

In one embodiment of the invention, a method for manufacturing a semiconductor arrangement is provided. The method includes forming at least one trench in a dielectric layer, thereby exposing a portion of a semiconductor substrate, forming a silicon-germanium buffer layer at least on the bottom of the at least one trench, forming a germanium seed layer on the silicon-germanium buffer layer and forming a germanium layer on the germanium seed layer.

In one embodiment of the invention, a semiconductor arrangement is provided. The semiconductor arrangement includes a semiconductor substrate, a dielectric layer disposed above the semiconductor substrate, at least one trench in the dielectric layer exposing a portion of the semiconductor substrate, a silicon-germanium buffer layer disposed above at least the bottom of the at least one trench, a germanium seed layer disposed above the silicon-germanium buffer layer and a germanium layer disposed above the germanium seed layer.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a cross-sectional view of a semiconductor arrangement in accordance with an embodiment of the invention;

FIGS. 2A to 2K show cross-sectional views illustrating processes for manufacturing a semiconductor arrangement in accordance with an embodiment of the invention;

FIG. 3 shows a flow diagram illustrating a method for manufacturing a semiconductor arrangement in accordance with an embodiment of the invention;

FIG. 4 shows a plot of temperature and flow of disilane (or silane) and diluted germane with time for selective epitaxial growth in a trench in accordance with an embodiment of the invention;

FIG. 5 shows a schematic of an epitaxial growth system

FIG. 6A shows a scanning electron micrograph (SEM) image at a corner of a 100×100 μm² square with SEG Ge deposited in SiO₂ defined Si window openings;

FIG. 6B shows a cross-sectional transmission electron microscope (XTEM) image at an edge of SEG Ge;

FIG. 6C shows a SEM image of a 0.6 μm×20 μm stripe SEG Ge;

FIG. 6D shows a SEM image of a 2×2 μm² square pad SEG Ge;

FIG. 6E shows a XTEM image of a 0.35 μm×20 μm stripe of SEG Ge with SiO₂ as dielectric;

FIG. 7A shows a SEM image of etched pits at an edge of a 100×100 μm² SEG Ge epitaxy, after Ge surface treatment (wet-etch) by CrO₂/HF solution;

FIG. 7B shows a SEM image of etched pits at a centre of a 100×100 μm² SEG Ge epitaxy, after Ge surface treatment (wet-etch) by CrO₂/HF solution;

FIG. 7C shows a SEM image (global view) of a surface of a 100×100 μm² SEG Ge epitaxy after Ge surface treatment (wet etch) by iodine (I₂/CHCOOH/HNO₃/HF) solution;

FIG. 7D shows a SEM image (localized view) of a surface of a 100×100 μm² SEG Ge epitaxy after Ge surface treatment (wet etch) by iodine solution;

FIG. 7E shows a plot of measured etch pit density (EPD) due to surface treatment by both CrO₂/HF and iodine solution as a function of SEG Ge dimensions;

FIG. 8 shows a micro-Raman spectra at a centre of 100×100 μm² SEG Ge at various sites of a wafer;

FIG. 9 shows a cross-sectional view of a vertical incidence photodiode structure;

FIG. 10 shows I-V curves for a sample of four devices with positive voltage as reverse bias;

FIG. 11 shows a cross-sectional view of a waveguide photodiode;

FIG. 12 shows a perspective view of a waveguide photodiode;

FIG. 13 shows a perspective view of a waveguide photodiode with nucleated Ge on the dielectric;

### DESCRIPTION

While embodiments of the invention have been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

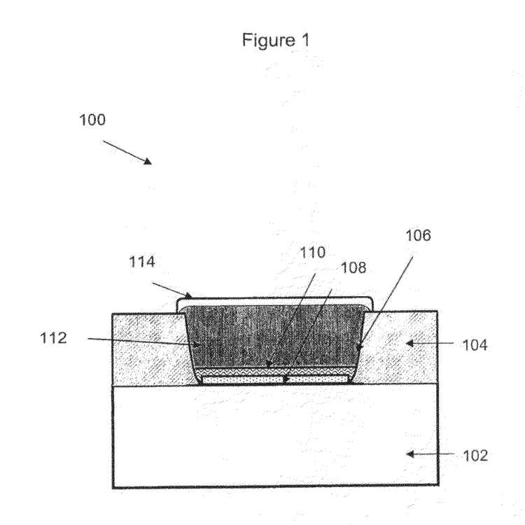

FIG. 1 shows a cross-sectional view of a semiconductor arrangement 100 in accordance with an embodiment of the invention. The semiconductor arrangement 100 includes a starting semiconductor substrate 102. The semiconductor substrate 102 is typically a bulk silicon (Si) substrate (or wafer) or a silicon-on-insulator (SOI) substrate. Nevertheless, any other suitable semiconductor material can be used for the semiconductor substrate 102. A dielectric layer 104 is deposited on the semiconductor substrate 102. The dielectric layer 104 may be an oxide, for example silicon oxide (SiO₂) or a combination of oxide and nitride (e.g. silicon nitride). Nevertheless, any other suitable dielectric material can be used for the dielectric layer 104. The semiconductor arrangement 100 further includes at least one trench 106 in the dielectric layer 104 exposing a portion of the semiconductor substrate 102. A silicon-germanium (SiGe) buffer layer 108 is disposed above at least the bottom of the trench 106, the SiGe buffer layer 108 being in contact with the semiconductor substrate 102. A germanium (Ge) seed layer 110 is disposed above the SiGe buffer layer 108 such that the Ge seed layer 110 wraps around the three edges of the SiGe buffer layer 108. Then a Ge epitaxial layer 112 is disposed above the Ge seed layer 110. Finally, a Ge protection layer or a capping layer 114 is disposed above the Ge epitaxial layer 112. The Ge protection layer 114 is typically made of Si.

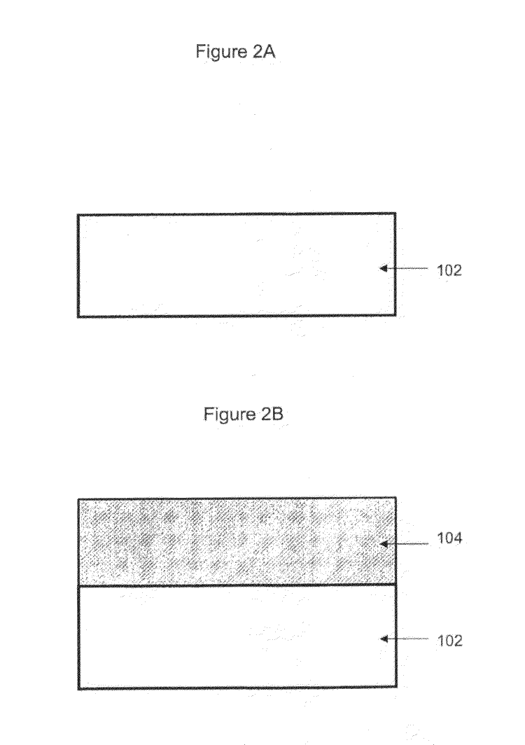

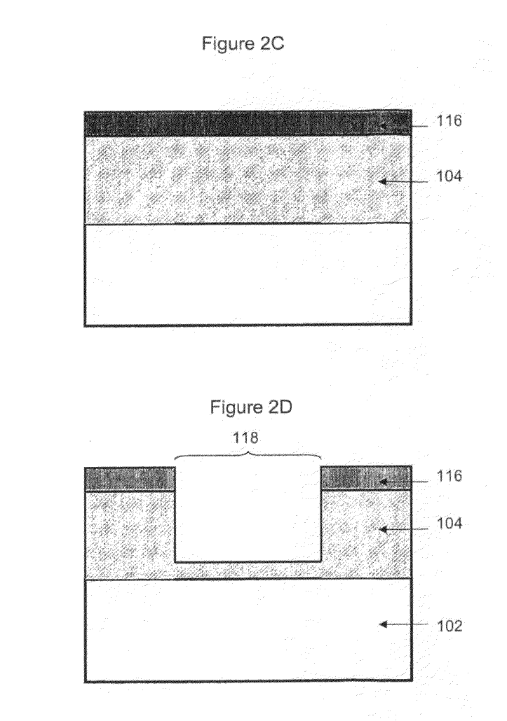

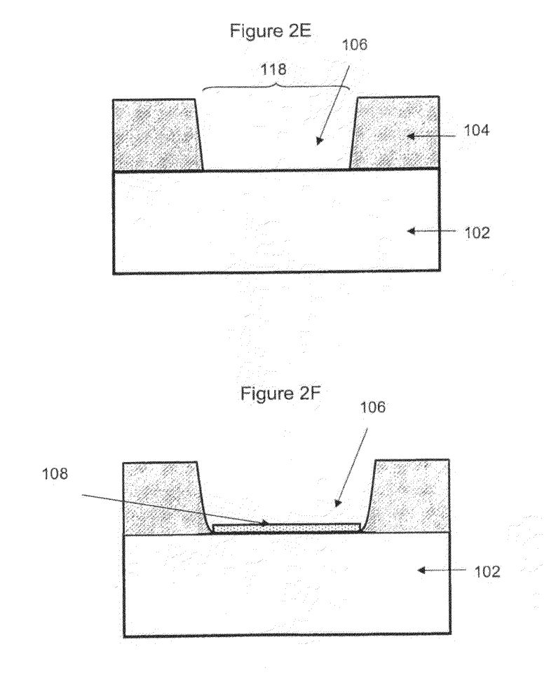

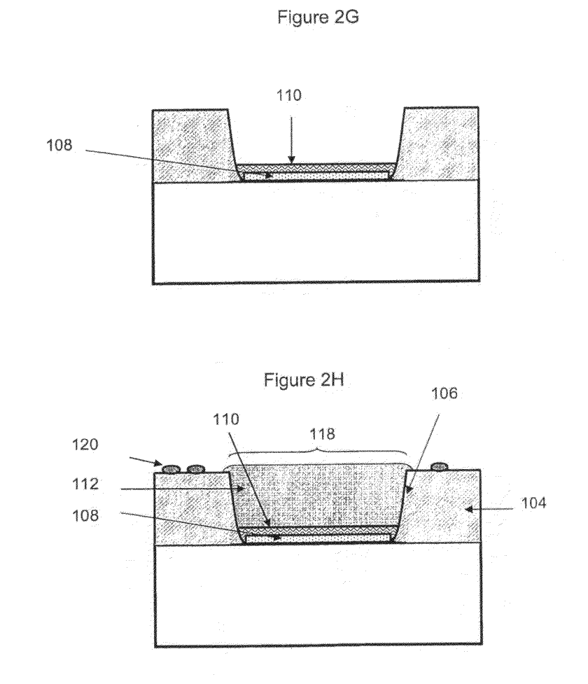

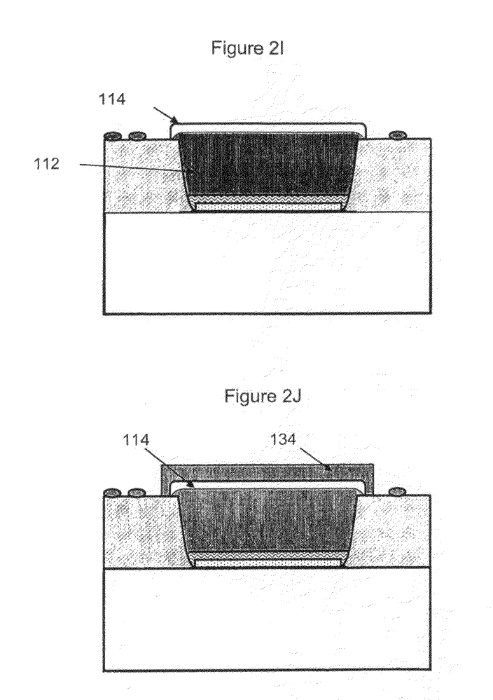

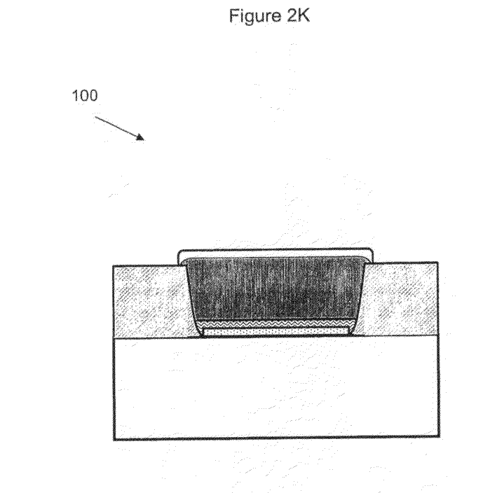

FIG. 2A to 2K show cross-sectional views illustrating processes for manufacturing a semiconductor arrangement in accordance with an embodiment of the invention.

FIG. 2A shows a starting semiconductor substrate 102. The semiconductor substrate 102 is typically a bulk Si substrate or an SOI substrate. The bulk Si substrate can be an 8 inch p-type Si (100) wafer with a resistivity in the range of about 6 to 9 Ωcm and the SOI substrate can be a p-type wafer with a resistivity of about 12 Ωcm. Nevertheless, any other suitable semiconductor material can be used for the semiconductor substrate 102. Before any deposition, the starting semiconductor substrate 102 may first be cleaned in ammonium hydroxide (NH₄OH):hydrogen peroxide (H₂O₂):de-ionized (DI) in the mixing ratio of 1:2:10 and then in hydrofluoric acid (HF):DI in the mixing ratio of 1:200 for about 2 minutes. This is followed by ultrasonic dry.

After cleaning, FIG. 2B shows a dielectric layer 104 deposited on the semiconductor substrate 102. The dielectric layer 104 may be an oxide or a combination of an oxide first, then a nitride. In an embodiment of the invention, the oxide is SiO₂ and the nitride is silicon nitride (Si₃N₄) but not so limited. In one embodiment of the invention, SiO₂ is deposited by plasma-enhanced chemical vapour deposition (PECVD). Nevertheless any suitable deposition process for depositing the SiO₂ may be utilized. The thickness of the SiO₂ is typically about 100 nm, but not so limited. In another embodiment of the invention, SiO₂ is thermally grown on the semiconductor substrate 102, followed by PECVD deposition of Si₃N₄. Nevertheless any suitable deposition process for the SiO₂ and Si₃N₄ may be utilized. The thickness of the thermally grown SiO₂ is typically about 120 nm, but not so limited. The thickness of the Si₃N₄ is typically about 50 nm.

Next, FIG. 2C shows a photoresist layer 116 deposited on the dielectric layer 104.

FIG. 2D shows that the photoresist layer 116 is then patterned by conventional photolithography techniques. Subsequently, using the patterned photoresist layer 116 as a mask, portions of the dielectric layer 104 not covered by the mask are partially etched away by an anisotropic etching process such as Reactive Ion Etching (RIE), leaving behind a dielectric layer 104 of about 100 Angstrom within a dielectric opening 118 on the semiconductor substrate 102.

FIG. 2E shows the removal of the photoresist layer 116, followed by wet etching of the remaining dielectric layer 104 in the dielectric opening 118 to form a trench 106 exposing a portion of the semiconductor substrate 102. The wet etching is carried out using diluted hydrofluoric acid (DHF):DI in the mixing ratio of 1:25. Subsequently, the partially formed semiconductor arrangement 100 is first cleaned in NH₄OH:H₂O₂:DI in the mixing ratio of 1:2:10 at a temperature of about 60° C. for about 5 minutes, then cleaned in DHF:DI in the mixing ratio of 1:200 for about 2 minutes. It is further rinsed in DI water and then dried in nitrogen (N₂).

After cleaning, selective epitaxial growth (SEG) in the trench 106 begins. The partially formed semiconductor arrangement 100 is loaded into a chamber of an epitaxial growth system, where the epitaxy commences with an in-situ high temperature cleaning at about 750° C. to 800° C. in N₂. Subsequently, as SiH₄ or Si₂H₆ is flown in the chamber, a thin Si layer (not shown) is grown on the semiconductor substrate 102 in the trench 106 at a temperature of between about 570° C. to 600° C. The thin Si layer has a thickness of about 30 nm, but not so limited. However, growth of the thin Si layer is optional. The thin Si layer is only required if the semiconductor substrate 120 is amorphized due to ion-implantation for doping purposes.

An interruption time of approximately 600 s is included as the temperature ramps down from about 750° C. to 350° C. prior to the flow of pure or diluted GeH₄ gas. The Ge epitaxy begins in FIG. 2F. As SiH₄ or Si₂H₆ and pure or diluted GeH₄ gases flow over the semiconductor substrate 102, a SiGe buffer layer 108 is deposited on the semiconductor substrate 102 in the trench 106. The thickness of the SiGe buffer layer 108 is about 13 nm to 30 nm, typically about 13 nm. The minimum thickness of the SiGe buffer layer 108 is about 7 nm to about 10 nm.

FIG. 2G shows growth of a Ge seed layer 110 on the SiGe buffer layer 108 at a temperature of 350° C. to 400° C. Similarly as GeH₄ gas flow over the SiGe buffer layer 108, the thermal decomposition of GeH₄ on the SiGe buffer 108 surface takes place resulting in Ge and H₂. In an embodiment of the invention, the thickness of the Ge seed layer 110 is about 30 nm to 50 nm, typically about 30 nm. In an embodiment of the invention, the minimum thickness of the Ge seed layer 110 is about 20 nm.

Then, there is a temperature stabilization time of about 2000 s where the temperature may be ramped up to about 550° C. to 600° C. FIG. 2H shows selective growth of Ge epitaxy layer 112 in the lithographically defined dielectric window opening 118 or trench 106 and formation of the nucleated Ge 120 on the dielectric layer 104. Ge epitaxy layer 112 refers to the Ge grown at high temperature (550° C. to 600° C.). The minimum thickness of Ge epitaxy layer 112 is about 30 nm. The typically overall thickness of Ge (Ge epitaxy layer 112 and Ge seed layer 110) is about 60 nm. In an embodiment of the invention, the thickness of the Ge epitaxy layer 112 is about 30 nm to 500 nm, for example about 400 nm to about 500 nm.

As Si₂H₆ or GeH₄ flows over the dielectric layer 104, decomposition of Si₂H₆ or GeH₄ results in the deposition of Si or Ge nucleation seeds 120 on the dielectric layer 104, respectively. A period of time will elapse for these nucleation seeds of Si or Ge 120 to form centers of nucleation of further Si or Ge on the dielectric layer 104 and then to finally form a layer of poly-Si or Ge. The time taken for the formation of a uniform layer of poly-Si or Ge on the dielectric layer 104 to completely cover the dielectric layer 104 underneath is known as the nucleation time. The incubation time is defined as the period from the point in time when constituent gases flow over the dielectric layer 104 to the time nucleated Si or Ge 120 on dielectric layer 104 first appears. The constituent gases are disilane (or silane) and diluted germane (or pure germane in general).

During the growth of low temperature SiGe buffer 108, the time for the flow of Si₂H₆ and GeH₄ is shortened such that this time period is shorter than the incubation time at the low temperature of about 350° C. to 400° C. Thereby, the limitation of species nucleation is overcome, while yet growing a layer of SiGe buffer 108 sufficiently thick to function to absorb dislocations due to lattice mismatch and misfit stress.

However, during the selective growth of the Ge epitaxy layer 112, as single crystal Ge 112 grow in thickness in the dielectric SEG window opening 118, nucleation of Ge begins to take place on the dielectric layer 104. As the particulates of Ge on dielectric layer 104 grow in size, these begin to compete for constituent gases and hence, deplete the species for single crystal growth of Ge 112 in the SEG window 118. As a result, the thickness of Ge epitaxial layer 112 on SEG window openings 118 reaches a limit. Since the nucleated Ge 120 on dielectric 104 is polycrystalline in nature, single crystal Ge 112 cannot extend its reach beyond the edges of the SEG window 118. In an embodiment of the invention, the maximum thickness of Ge epitaxial layer 112 in the process is about 400 nm to 500 nm. In addition, during the growth of two-step Ge layers over the low temperature SiGe buffer 108, dislocation appears at the interface between Ge layer (Ge epitaxial layer 112 and Ge seed layer 110) and the SiGe buffer layer 108. The dislocations loop back to the Ge/SiGe interface. The extent of the dislocation loops is estimated to be about the height or thickness of the Ge-seed layer 110. Therefore, in an embodiment of the invention, the minimum thickness of the Ge epitaxy 112 should be about 30 nm so that the Ge epitaxy surface 112 is about 30 nm above the extent of the dislocation loops.

FIG. 2I shows growth of a protective capping layer 114 over the Ge epitaxy layer 112 at a temperature of 550° C. to 600° C. The capping layer 114 is typically Si, but not so limited. In an embodiment of the invention, the thickness of the capping layer 114 is about 3 nm to 10 nm, typically about 4 nm. The growth of the capping layer 114 or Ge protection layer is to protect the Ge epitaxial layer 112, but may be optional.

FIG. 2J shows deposit of a photoresist layer 134 on the capping layer 114. Reverse mask photolithography may be used to form the protective photoresist layer 134 on the capping layer 114.

FIG. 2K shows the final semiconductor arrangement 100 where the nucleated Ge 120 on the dielectric 104 are removed by dry etching in a suitable etching solution for example chlorine (Cl₂) or Cl₂/hydrogen bromide (HBr) either in-situ or ex-situ. The duration for the flow of the etching solution may be about 180 s. The photoresist layer 134 is removed after etching of nucleated Ge 120 is completed.

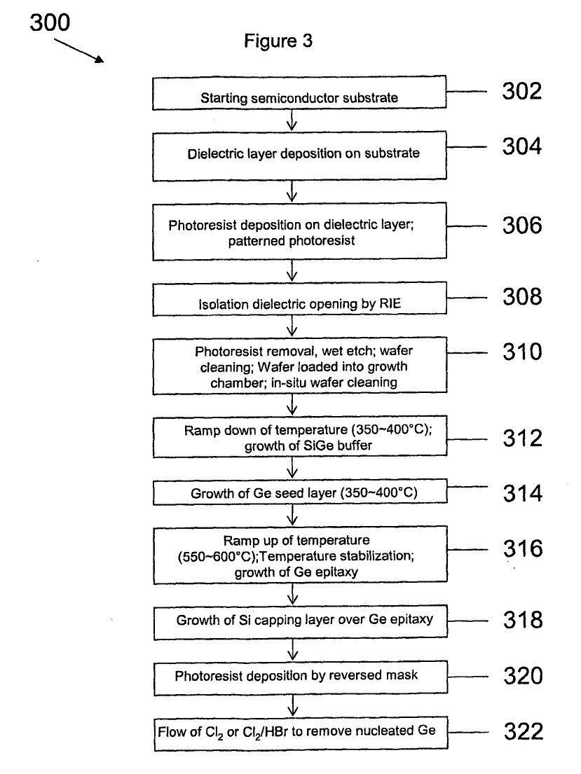

FIG. 3 shows a flow diagram illustrating a method for manufacturing a semiconductor arrangement 100 in accordance with an embodiment of the invention. The method 300 begins at 302 with a starting semiconductor substrate 102. Next, in 304, a dielectric layer 104 is deposited on the semiconductor substrate 102. Further, in 306, a photoresist layer 116 is deposited on the dielectric layer 104. The photoresist layer 116 is patterned using photolithography techniques. Subsequently, in 308, using the patterned photoresist 116 as a mask, portions of the dielectric layer 104 not covered by the mask are partially etched away by an anisotropic etching process such as RIE, leaving behind a dielectric layer 104 of about 100 Angstrom within a dielectric opening 118 on the semiconductor substrate 102. In 310, the photoresist layer 116 is removed, followed by wet etching of the remaining dielectric layer 104 in the dielectric opening 118 to form a trench 106 exposing a portion of the semiconductor substrate 102. The partially formed semiconductor arrangement 100 is cleaned and further loaded into a growth chamber for further in-situ high temperature cleaning. In 312, the temperature is ramped down to about 350° C. to 400° C. and a SiGe buffer layer 108 is grown on the exposed portion of the semiconductor substrate 102 in the trench 106. In 314, a Ge seed layer 110 is grown on the SiGe buffer layer 108 at approximately the same temperature as that for the growth of the SiGe buffer layer 108. Then, in 316, the temperature is ramped up to about 550° C. to 600° C. After a period of temperature stabilization, a Ge epitaxial layer 112 is grown over the Ge seed layer 110. Next, in 318, a capping layer 114 is grown over the Ge epitaxy layer 112. Then, in 320, a photoresist layer 134 is formed by reversed mask covering the capping layer 114. Finally, in 322, Cl₂ or Cl₂/HBr is flown in the growth chamber to remove the nucleated Ge 120. Furthermore, the photoresist layer 134 is removed after etching of nucleated Ge 120 is completed.

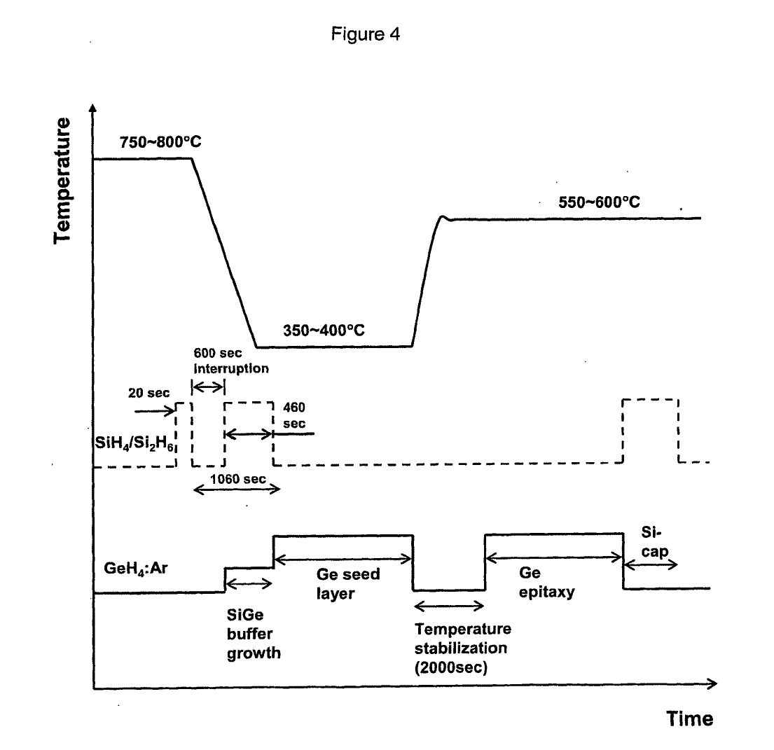

FIG. 4 shows a plot of temperature and flow of disilane (or silane) and diluted germane with time for selective epitaxy growth in a trench in accordance with an embodiment of the invention. The SEG process commences with an in-situ high temperature cleaning at about 750° C. to 800° C. in N₂. Subsequently, SiH₄ or Si₂H₆ is flown in the chamber for a duration of about 20 s. A thin Si layer is grown on the semiconductor substrate 102 in the trench 106 at a temperature of between about 570° C. to 600° C. The thin Si layer has a thickness of about 30 nm, but not so limited. An interruption time of approximately 600 s is included as the temperature ramps down from about 750° C. to 350° C. prior to the flow of pure or diluted germane (10% GeH₄:Ar). As the temperature is lowered to about 350° C. to 400° C., SiH₄ or Si₂H₆ and pure or diluted germane (10% GeH₄:Ar) gases are flowed in the growth chamber of the UHVCVD growth system for a duration of about 460 s resulting in growth of a SiGe buffer layer 108 in the trench 106. For growth of the Ge seed layer 110, the temperature is maintained at the same range of between about 350° C. to 400° C. Only pure or diluted germane gas is flown in the growth chamber for duration of about 1000 s to about 3000 s. The flow of the pure or diluted germane gas is at a higher volume compared to flow of the pure or diluted germane gas during the growth of the SiGe buffer layer 108. Subsequently, there is a temperature stabilization period of about 2000 s where the temperature in the growth chamber increases from the range of about 350° C. to 400° C. to a higher range of between about 550° C. to 600° C. and is followed by a settling time. A sufficient time is given for temperature uniformity to ensure grown film uniformity in thickness and composition. There is no flow of any gas in the chamber during this temperature stabilization period. Further, for growth of Ge epitaxy layer 112, the temperature is maintained at the range between about 550° C. to 600° C. Pure or diluted germane gas is then flowed for duration of about 2000 s to 3000 s and the flow rate is comparable to the flow rate during the growth of the Ge seed layer 110. The time for flowing pure or diluted germane gas is determined by the target thickness of the Ge epitaxy layer 112. Then with the temperature maintaining at the same range of between about 550° C. to 600° C., only SiH₄ or Si₂H₆ is flown for a duration of about 100 s to 150 s for the growth of the Si capping layer 114.

FIG. 5 shows a schematic of an epitaxial growth system. The epitaxial growth system 144 is a single wafer cold wall UHVCVD system, for example Canon ANELVA 1-2100SRE. The UHVCVD system 144 include two turbo molecular pumps 122, a water cooled cold wall chamber 124, a thermo couple 126, a pyrometer 128, a susceptor 130, a heater assembly 132 and two gas inlets 146. The two gas inlets 146 are namely, one for pre-mixed epi-growth gases, such as germane, disilane (phosphine, diborane for doping), and the other for chlorine gas. This is because chlorine is an etchant while the rest of the gases are for epitaxial growth. A semiconductor substrate or wafer 102 is mounted on the susceptor 130, which is typically a silicon carbide coated graphite disc, to receive uniform deposition of materials on the semiconductor substrate 102 surface. The susceptor 130 may be rotated by a motor during deposition to further improve the uniformity of the deposited materials. Typical process pressure in the chamber is between about 10⁻³ Pa and about 1 Pa. For most cases of chemical vapor deposition (CVD) growth system, epitaxial growth arises from both gas phase reactions and wafer surface reactions. For gas phase reaction, precursor gases premixed in a manifold and as the gas mixture reaches the vicinity of high temperature zone above the wafer or semiconductor substrate 102, gas reaction and decomposition take place and result in deposition of the epitaxy layers. Wafer surface reaction consists of constituent precursor gases reaching the surface of the wafer or semiconductor substrate 102, experiencing high temperature, and decomposition results in adsorption of intermediate reactants and desorptions of species from the semiconductor substrate surface. A net rate of adsorption onto semiconductor substrate 102 surfaces results in growth of thin films.

In one embodiment of the current invention, at the specified pressure range, gas phase reactions are minimized while wafer surface reactions are dominant. The growth rate is dependent on the wafer surface temperature. Ultimate pressure of the chamber of the UHVCVD growth system 144 is of the order of about 10⁻⁶ Pa. 100% disilane (Si₂H₆) gas and diluted germane (10% GeH₄:Ar) gases for example are introduced from one of the gas inlets 146 of the chamber wall 124. The semiconductor substrate 102 is heated from the backside. Growth chamber wall 124 and the shroud (wall lining of the growth chamber) for the heater chamber 124 are water-cooled in order to confine gas decomposition only on the surface of the semiconductor substrate 102. Alternative Si source gases are silane (SiH₄) and dichloro-silane (SiH₂Cl₂) and alternative Ge source gas is pure germane (GeH₄). Using ultra-high vacuum (UHV) range of gas pressure, device grade epitaxy can be grown at a low temperature range of about 550° C. to about 600° C.

For wafer surface reactions, Si or Ge growth arises from the heterogeneous decomposition of SiH₄, Si₂H₆ or GeH₄ into Si or Ge and hydrogen (H₂), respectively. Taking Si growth as an example, the thermal decomposition of SiH₄ on wafer surface takes place according to a two-step adsorption or desorption and heterogeneous reaction mechanism. The chemical equations are:

SiH₄(g)+* [symbol] SiH₄* (1)

SiH₄* [symbol] Si(s)+2H₂(g) (2)

where * indicates a free surface site and SiH₄* is adsorbed silane. The H₂ gas also experience dissociative adsorption on the free surface sites,

H₂(g)+2* [symbol] 2H* (3)

2* indicates 2 free surface sites. Since H* occupies one surface site, H* has been known to inhibit silane adsorption.
For Si₂H₆, the chemical reactions are:

Si₂H₆(g)+2* [symbol] Si₂H₆* (4)

Si₂H₆* [symbol] 2Si(s)+3H₂(g) (5)

For Ge growth, the chemical equations are:

GeH₄(g)+* [symbol] GeH₄* (6)

GeH₄* [symbol] Ge(s)+2H₂(g) (7)

To account for SiGe growth using Si₂H₆ and GeH₄ gases on Si substrate, typical chemical reaction equation on the surface of wafer are:

Si₂H₆*+2GeH₄* [symbol] 2SiGe(s)+5H₂(g) (8)

### Experimental Results

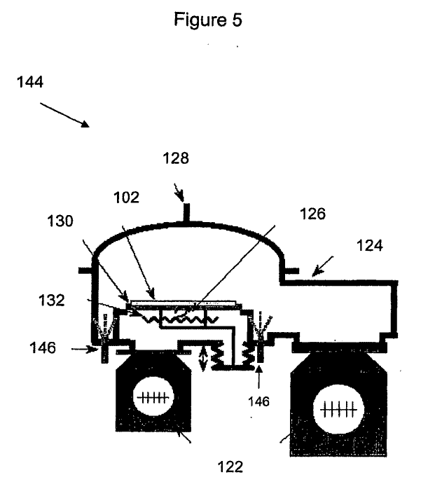

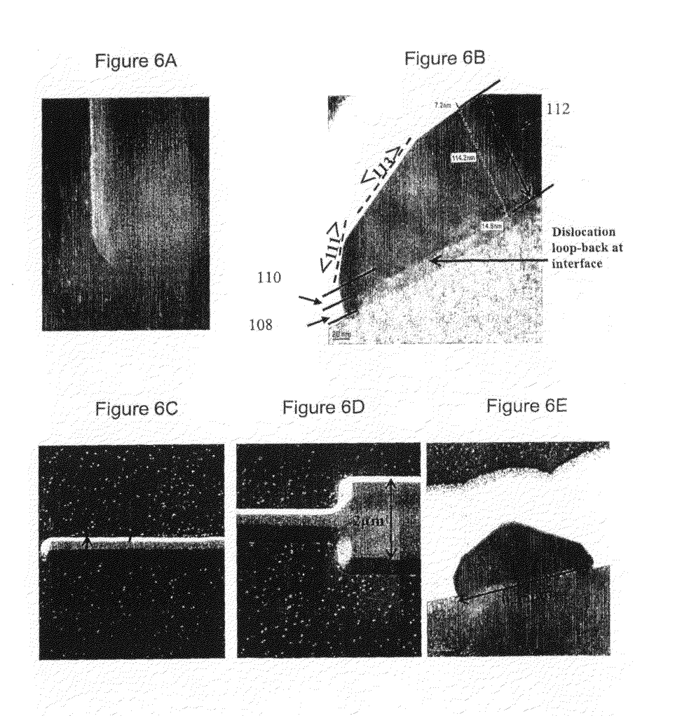

FIG. 6A shows a scanning electron micrograph (SEM) image at a corner of a 100×100 μm² square with SEG Ge 158 deposited in SiO₂ defined Si window openings. SEG Ge includes the SiGe buffer layer, 108, the Ge seed layer 110 and the Ge epitaxial layer 112. The edges of the square opening were aligned along (100) direction.

FIG. 6B shows a cross-sectional transmission electron micrograph (XTEM) image at an edge of SEG Ge 158. The measured thicknesses of Ge epitaxy 112 and SiGe buffer 108 are about 114.2 nm and 14.8 nm respectively. The double facets composed of the (111) and (311) facets are typical also for SEG of Si. The evolution of the facets consists of first growth of (311) facet followed by formation of (111) facet. Development of each faceting plane is due to the difference in growth rates between (100) plane and the other faceting planes under low partial pressure growth condition. The edges of the 100×100 μm² opening were aligned along (100) direction. In FIG. 6B, SEG Ge 158 is in the lateral direction from the edge of SiGe buffer 108. That is, the Si_{0.8}Ge_{0.2} buffer 108 was first grown selectively and, subsequently, Ge seed layer 110 wrapped around the edges of the Si_{0.8}Ge_{0.2} epitaxy 108. The non-selectivity of Ge epitaxy 112 sets in as the Ge epitaxial thickness becomes thicker than about 300 nm. This also means that particulates of nucleated Ge will form on the dielectric 104 after this SEG Ge 158 thickness. The particulates of nucleated Ge can be selectively removed via in-situ etching by Cl₂ gas flow.

SEG Ge 158 is also done on PECVD Si₃N₄ patterned window openings. It is observed that facet formation has no dependence on the nature of the dielectric. Dislocation induced contrast of the XTEM indicates no propagation of dislocations to the surface. The surface roughness was measured by Atomic Force Microscopy (AFM). The root-mean-square (rms) roughnesses for 10×10 μm² scanned area were 1.14 nm and 1.45 nm for SEG Ge 158 and blanket Ge on non-patterned substrate, respectively. There is reduction in roughness on SEG epitaxy. These are improvement in comparison to 3.2 nm of rms roughness for 1 μm of Ge epitaxy 112 on bi-layer SiGe buffer 108 on Si(100) substrate 102.

FIG. 6C show a SEM image of a 0.6 μm×20 μm stripe of SEG Ge 158 and FIG. 6D shows a SEM image of a 2×2 μm² square pad of SEG Ge 158. In FIG. 6C and FIG. 6D, the dielectric 104 is SiO₂. The measured width of SEG Ge 158 stripe is about 0.7 μm due to overgrowth of Ge over the 0.6 μm opening. FIG. 6E shows a XTEM image of a 0.35 μm×20 μm stripe of SEG Ge 158 with SiO₂ as dielectric 104.

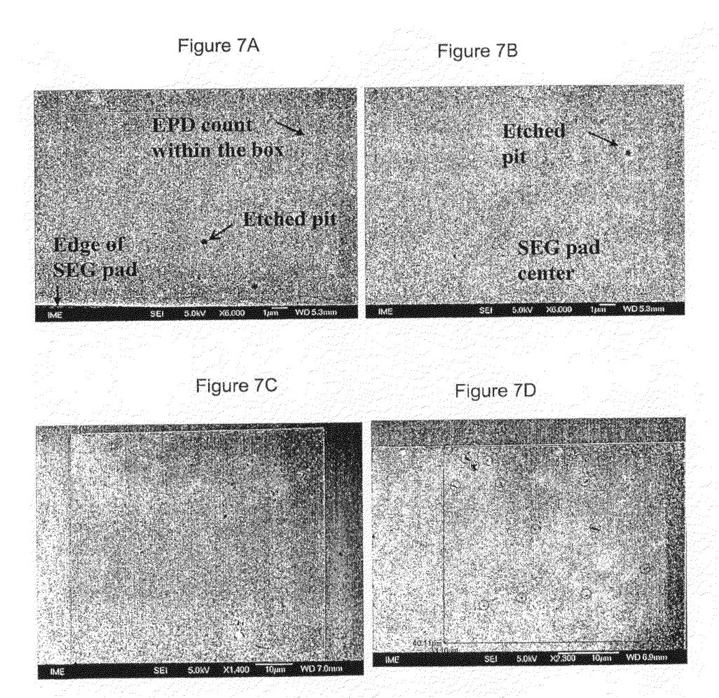

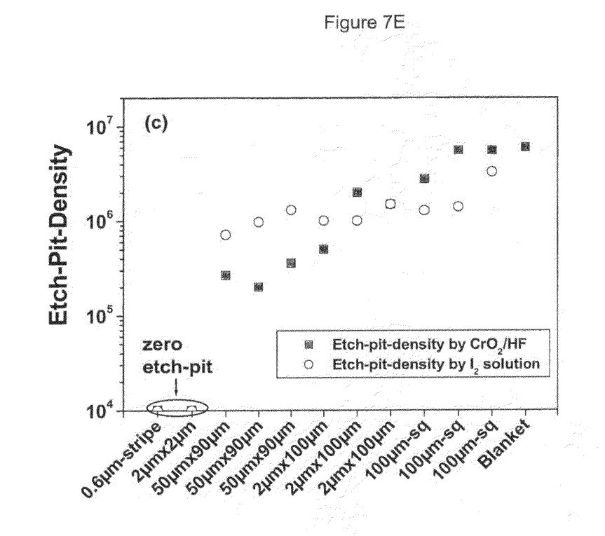

FIG. 7A and FIG. 7B show SEM images of etched pits (EP) at an edge and at a centre of a 100×100 μm² SEG Ge epitaxy 158 respectively, after Ge surface treatment (wet-etch) by chromium dioxide (CrO₂) and hydrofluoric acid (HF) solution. The box in which etch pit density (EPD) is counted has a dimension of 12 m×15 μm. In 100×100 μm² SEG Ge, etched pits tend to accumulate at the edge. In some area, practically no EP was observed at the centre of the 100×100 μm² SEG Ge for the same observation area. The average EPD for 100×100 μm² was counted to be about 2.8×10⁶ cm⁻² to 5.6×10⁶ cm⁻².

FIG. 7C shows a SEM image (global view) of a surface of a 100×100 μm² SEG Ge epitaxy 158 after Ge surface treatment (wet etch) by iodine (I₂/CHCOOH/HNO₃/HF) solution or I₂ solution. FIG. 7D shows a SEM image (localized view) of a surface of a 100×100 μm² SEG Ge epitaxy after Ge surface treatment (wet etch) by iodine solution. FIG. 7C and FIG. 7D show the etch-pits due to I₂ solution. The characteristic feature of the etch-pits is shown on the figures itself. SEM image arises from secondary electrons emitting from the surface of the sample under observation. If the area under observation is a pit, little or no secondary electrons are emitting from the area and thus, appear as dark areas on the image.

The key differentiation in the current invention is its contribution to a lower EPD for reduced growth area without the use of cyclic annealing, thus, simplifying processing step for integration to mainstream CMOS process, by using a thin layer of low temperature Si₁₋ₓGeₓ buffer. The key challenge for the growth of Ge on Si is the mismatch in lattice constant and thermal coefficient of expansion (contraction). After the growth of Ge on Si at about 550 to 600° C. and during cool down, dislocations arise from lattice mismatch of the two materials, as well as interfacial stress due to mismatch in thermal coefficients of Ge and Si. Such interfacial stress reduces with reduction in the SEG-Ge epitaxial dimensions. Hence, when dimensions are reduced beyond certain point, interfacial stress becomes insignificant to cause dislocation and EP's.

FIG. 7E shows a plot of measured EPD due to surface treatment by both CrO₂/HF and iodine solution as function of SEG Ge epitaxy 158 dimensions. The EPD after treatment by CrO₂/HF and I₂ solutions are shown respectively. FIG. 7E shows a general trend of reduction of EPD vs SEG areas. For 50×90 μm² SEG-Ge area, it is just statistical variation that EPD counted for CrO₂/HF is lower than that by I₂ solution. EPD were derived from counting the number of EP's in a 2-D box of SEM image. Typical size of the box is: 15×20 μm². The key information is the general trend of reduction of EPD with SEG areas. Two types of etchant solutions were used for comparison and for better credibility of results.

While 100×100 μm² SEG Ge 158 has EPD close to the full-wafer Ge epitaxy, the EPD decreases as the growth area is reduced. EPD decreases to about 10⁵ cm⁻² for 50 μm×90 μm pad. No EPD was observed for 2×2 μm² and 0.6 μm×20 μm stripe of SEG Ge. These small areas were on the same die as the 50 μm×90 μm pad. EPD reduction with growth area is typical of the theoretical expectation due to the suppression of area dependent misfit dislocation sources, and also nearness of edges as sinks for TD. Although such EPD reduction with area has been reported by other methods such as in publication “high-quality Ge epilayers on Si with low threading-dislocation densities”, Hsin-Chiao Luan et al., Applied Physics Letters, Vol 75, Number 19, November 1999 and U.S. Pat. No. 6,635,110, the key differentiation in the current invention is its contribution to a lower EPD for the same growth area, utilizing low temperature Si_{0.8}Ge_{0.2} buffer as sink for misfit dislocation.

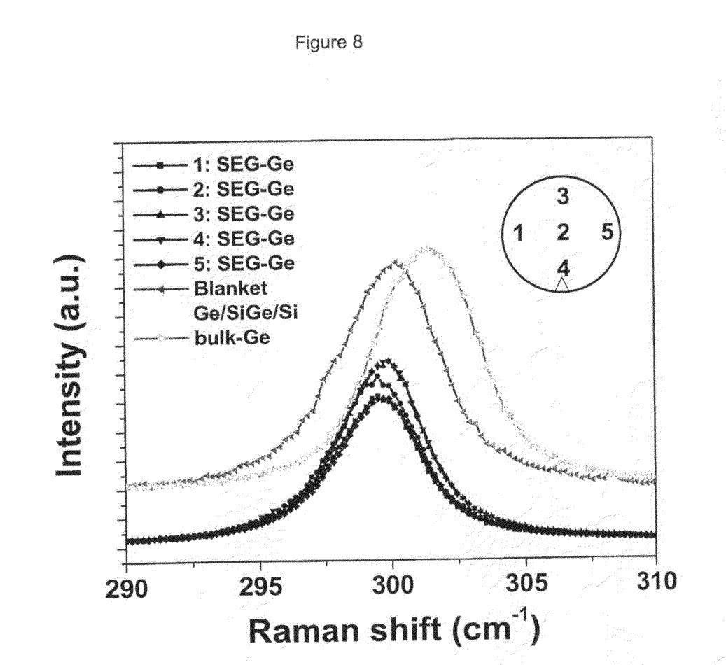

FIG. 8 shows a micro-Raman spectra at a centre of 100×100 μm² SEG Ge at various sites of the wafer (points 1 through 5). Spectra of blanket Ge epitaxy on Si (100) substrate with an ultra-thin Si_{0.8}Ge_{0.2} buffer and that of bulk Ge substrate are also plotted for comparison. The wavelength of Ar+ laser excitation is about 514 nm. No shift in the Raman phonon peak from full wafer to 100×100 μm² SEG Ge epitaxies was detected within the error of the instrument. The bulk Ge substrate has a Ge—Ge optical phonon peak at about 301.4 cm⁻¹. The optical phonon signals from both blanket Ge and 100×100 μm² SEG-Ge epitaxies peak at about 300 cm⁻¹ showing a small shift indicating residual tensile strain in the Ge epitaxies for both cases. The residual tensile strain varies in the range of about 0.29% to 0.36%, which is known to arise from differences in linear coefficients of thermal expansion of Si and Ge. The penetration depth of the laser beam into the Ge epitaxy is about 15 nm. There is no significant difference in the full-width-at-half-maximum (FWHM) of the phonon peaks thereby indicating no significant difference in the optical quality of Ge films for both blanket and 100×100 μm² SEG cases.

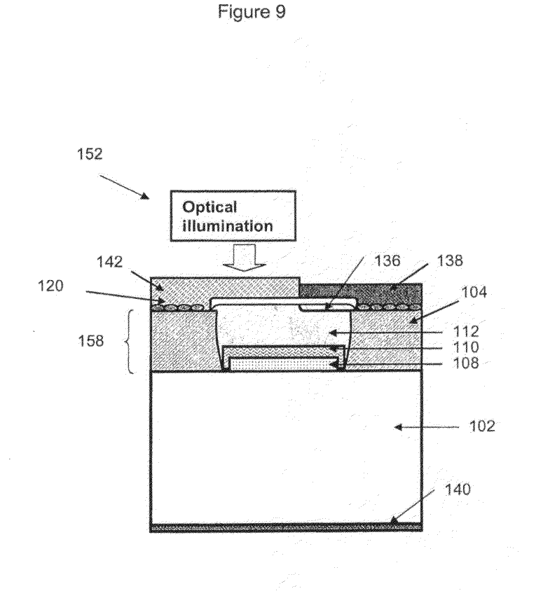

To assess if the Ge/Si material is viable for application as photo-detector, the 100×100 μm² SEG Ge 158 with thickness of about 114.2 nm was fabricated into a photodiode. FIG. 9 shows a cross-sectional view of a vertical incidence photodiode structure 152. P-i-N junction is formed by a semiconductor substrate 102 for example a P-type substrate, intrinsic SEG Ge 158 (SiGe buffer layer 108, Ge seed layer 110 and Ge epitaxial layer 112) and N+ shallow implanted arsenic doping on Ge epitaxial layer 112 so that the Ge/SiGe/Si interface is in the depletion region. The top cathode 138 consists of aluminum (Al) electrode in contact with N+ Ge 136 (contact area 25 μm×100 μm). The estimated N+ junction 136 depth is about 30 nm. Al electrode is formed by lift-off process. The bottom substrate contact, typically Al, forms anode 140 in contact to ground. Nucleated Ge 120 exists on the dielectric 104 and it is not necessary to remove the nucleated Ge 120. The nucleated Ge 120 is further covered by a dielectric layer 142, typically SiO₂.

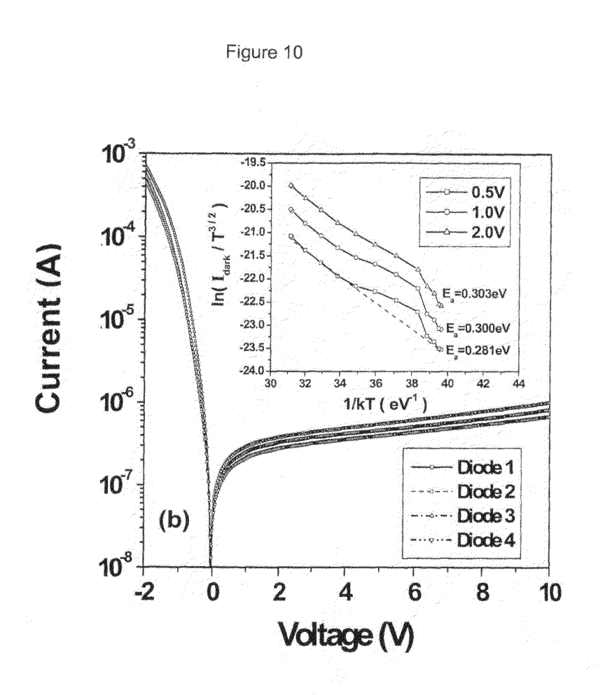

Dark current is investigated since it contributes to photo-receiver sensitivity. FIG. 10 shows current-voltage (I-V) curves for a sample of four devices with positive voltage as reverse bias. The minimum dark current density at about 1V bias at room temperature (RT) is about 8.6 mA/cm² and the average dark current density is about 10 mA/cm². The minimum dark current density increases to about 11 mA/cm² at about 2 V. These are considered as low dark current densities in that the thickness of Ge is only about 114.2 nm above the Ge/SiGe hetero-interface. In comparison, dark current density for Ge prepared by two-stage Ge growth coupled with cyclic annealing is typically about 20 mA/cm². The current invention is comparable in performance for application in Ge/Si photo-detector, with the advantage of being SEG and without using high temperature cyclic annealing, thus, making it useful for achieving integration to mainstream CMOS processes.

It is found that I_{dark} to temperature relation follows equation (9) for n equals to 3/2, rather than 3. Eₐ is the activation energy for leakage current, Vₐ, the applied bias voltage, k is Boltzmann constant and T is temperature. The insert of FIG. 10 shows the plot of ln(I_{dark}/T^{3/2}) vs 1/kT for reverse bias of 0.5V, 1V and 2V respectively. Eₐ, extracted from the slope of the plot, gives an average value of 0.3 eV, which is roughly half the band-gap of Ge (0.66 eV) at room temperature (RT). This implies that leakage current in the diode is dominated by trap-assisted electron-hole generation in the depletion region, also known as Shockley-Hall-Read process.

I_{dark}=CTⁿe^{-E}^{ₐ}^{/kT}(e^{qV}^{ₐ}^{/2kT}−1), C is arbitrary constant. (9)

Ge nucleates on the isolation dielectric 104 during the process of selective epitaxial growth of Ge or SiGe on trenches 106 with exposed Si. For vertical incidence photodiode as shown in FIG. 9, since optical power is injected into Ge epitaxy 112 from the top and no light propagation is allowed in the in-plane direction of the wafer, presence or absence of nucleated Ge particles 120 on isolation dielectric 104 will not affect the optical aspect of operation of the device. However, if there are adjacent planar electronics devices monolithically present on the same die as the vertical incidence photodiode, the nucleated Ge 120 may form electrical leakage path to the adjacent electronics devices and nucleated Ge 120 may need to be removed for proper electronics operations of the device.

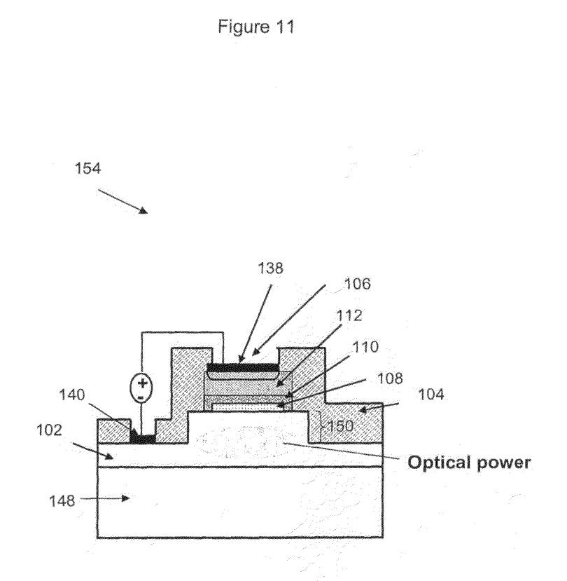

FIG. 11 shows a cross-sectional view of a waveguide photodiode. The waveguide photodiode 154 is a Si/SiO₂ waveguide having a typical rib waveguide structure. The waveguide photodiode 154 includes a buried oxide 148 and a semiconductor substrate 102 for example a p-type SOI substrate deposited on the buried oxide 148. A protrusion 150 is formed on the Si layer of the SOI substrate 102. A dielectric layer 104, for example SiO₂ is deposited over the SOI substrate 102. The waveguide photodiode 154 further includes at least one trench 106 in the dielectric layer 104 above the protrusion 150, exposing a portion of the SOI substrate 102. A SiGe buffer layer 108 is disposed above at least the bottom of the trench 106, the SiGe buffer layer 108 being in contact with the SOI substrate 102. A Ge seed layer 110 is disposed above the SiGe buffer layer 108 such that the Ge seed layer 110 wraps around the three edges of the SiGe buffer layer 108. Then a Ge epitaxial layer 112 is disposed above the Ge seed layer 110. The Ge epitaxial layer 112 is doped with n-type dopants to render it n-type. A metal contact 138, serving as the cathode is deposited on the Ge epitaxial layer 112 for connection with another metal contact, serving as the anode 140 on the SOI substrate 102. The contacts 138, 140 are typically made of Al.

The fabrication process of the waveguide photodiode 154 is as such. First, partial dry etching of Si on the SOI 102 is performed to form a protrusion 150 (i.e. a central thick Si rib flanked by thinner Si with SiO₂ at the bottom). Such structure is designed so as to confine the optical power to the centre of the rib as light-wave propagates down the rib waveguide structure. Upon completion of dry etching of Si to form the rib, SiO₂ 104 (or dielectric with refractive index less than Si) is deposited. Dielectric openings 118 were formed by opening-lithography, partial dry etch of SiO₂ 104, wet etching of remaining dielectric to expose Si surface, and followed by SEG-Ge 158 growth.

For Ge or Si waveguide photodiode 154, optical power is directed along Si/SiO₂ waveguide unlike the vertical incidence photodiode 152 where optical power is injected into Ge epitaxy layer 112 from the top. For waveguide photodiode 154, Si is the channel in which optical power flows and SiO₂ 104 is the cladding of the waveguide. No nucleated Ge 120 remains on dielectric layer 104.

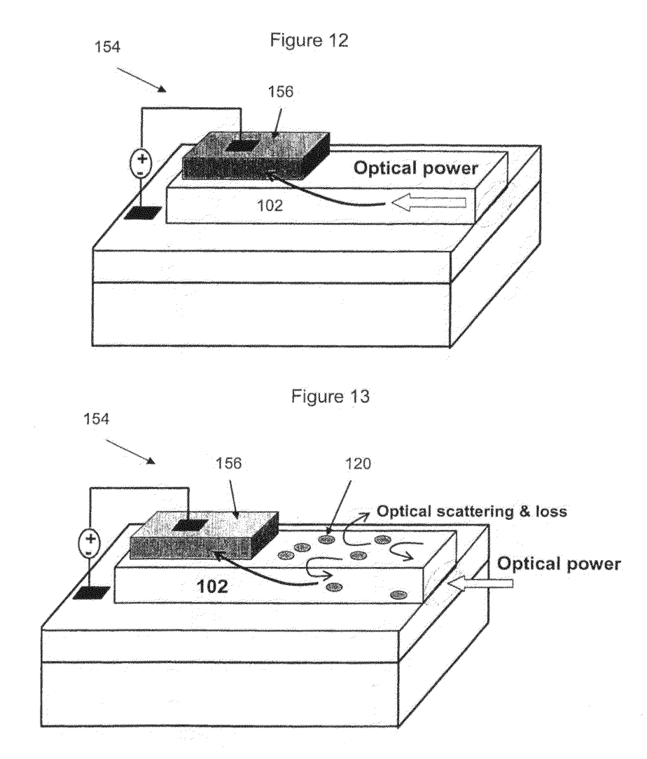

FIG. 12 shows a perspective view of a waveguide photodiode 154. After lightwave is directed along Si/SiO₂ waveguide 102, optical power is evanescently coupled to the Ge or Si absorber block 156 which is epitaxially grown on Si/SiO₂ waveguide 102 by selective epitaxy.

FIG. 13 shows a perspective view of a waveguide photodiode 154 with nucleated Ge 120 on the dielectric layer 104. The dielectric layer 104 is shown in FIG. 11 but is not shown in FIG. 13. Although the dielectric layer 104 is not shown, it is usually a thin layer on the wall of the SOI rib waveguide. The particulates of nucleated Ge 120 are on the dielectric layer 104 surface. These nucleated Ge 120 are formed during the selective epitaxial growth of Ge in the exposed Si substrate surface. Depending on the fabrication process, if the nucleated Ge 120 is not removed while an additional dielectric layer is deposited on the structure, these Ge particulates 120 can be embedded in the dielectric layer. The SEG Ge is formed at the same time as nucleated Ge on the dielectric layer. For optical aspect of operation of the Si or Ge waveguide photodiode, nucleated Ge 120 on the isolation dielectric layer 104 forms optical scattering centers of lightwave directed along Si/SiO₂ waveguide 102, since refractive index of Ge is 4.2 and refractive index of Si is 3.55. High refractive index material (such as Ge) tends to couple optical power to it as light wave propagates through the Si/SiO₂ waveguide 102. These Ge particles 120 cause light wave scattering and optical losses, and lower the external quantum efficiency of the waveguide photodiode 154.

1. A method for manufacturing a semiconductor arrangement, the method comprising:
forming at least one trench in a dielectric layer, thereby exposing a portion of a semiconductor substrate;
forming a silicon-germanium buffer layer at least on the bottom of said at least one trench;
forming a germanium seed layer on said silicon-germanium buffer layer; and
forming a germanium layer on said germanium seed layer.

2. The method of claim 1, wherein said semiconductor substrate is a silicon substrate.

3. (canceled)

4. The method of claim 1, wherein said silicon-germanium buffer layer is formed using a low temperature process or a vapor deposition process.

5-8. (canceled)

9. The method of claim 4, wherein said vapor deposition process comprises applying a disilane gas component and a germane gas component.

10. (canceled)

11. The method of claim 1, wherein said germanium seed layer is formed using a low temperature process or a vapor deposition process.

12-14. (canceled)

15. The method of claim 1, wherein said germanium layer is formed using a process selected from the group consisting of an epitaxial growth process, a high temperature process and a vapor deposition process.

16-17. (canceled)

18. The method of claim 1, wherein said germanium layer is formed using a high temperature process in a temperature range from about 500° C. to 650° C.

19. (canceled)

20. The method of claim 1, further comprising: forming said dielectric layer on said semiconductor substrate.

21-22. (canceled)

23. The method of claim 1, further comprising: forming a germanium protection layer on said germanium layer.

24. (canceled)

25. The method of claim 1, further comprising: removing germanium material deposited on the upper surface of said dielectric layer.

26. The method of claim 25, wherein said germanium material is removed using a dry etch process.

27. (canceled)

28. A semiconductor arrangement, comprising:
a semiconductor substrate;
a dielectric layer disposed above said semiconductor substrate;
at least one trench in said dielectric layer exposing a portion of said semiconductor substrate;
a silicon-germanium buffer layer disposed above at least the bottom of said at least one trench;
a germanium seed layer disposed above said silicon-germanium buffer layer; and
a germanium layer disposed above said germanium seed layer.

29. The semiconductor arrangement of claim 28,
wherein said semiconductor substrate is a silicon substrate.

30. The semiconductor arrangement of claim 29,
wherein said silicon substrate is a bulk silicon substrate or a silicon-on-insulator substrate.

31-32. (canceled)

33. The semiconductor arrangement of claim 28, wherein said germanium layer is an epitaxially grown germanium layer.

34. (canceled)

35. The semiconductor arrangement of claim 28, wherein said dielectric layer comprises a material selected from the group consisting of an oxide, a nitride and a combination thereof.

36. (canceled)

37. The semiconductor arrangement of claim 28, further comprising: a germanium protection layer disposed above said germanium layer.

38. The semiconductor arrangement of claim 37, wherein said germanium protection layer is made of silicon or a photoresist material.

39. An optical component comprising:
a semiconductor arrangement, said semiconductor arrangement, comprising:
a semiconductor substrate;
a dielectric layer disposed above said semiconductor substrate;
at least one trench in said dielectric layer configured to expose a portion of said semiconductor substrate;
a silicon-germanium buffer layer disposed above at least the bottom of said at least one trench;
a germanium seed layer disposed above said silicon-germanium buffer layer; and
a germanium layer disposed above said germanium seed layer.

40. The optical component of claim 39, being configured as a waveguide or a photodiode.
